(19) United States
(12) Patent Application Publication
(10) Pub. No.: US 2026/0005049 A1
(43) Pub. Date: Jan. 1, 2026

(54) END EFFECTOR

(71) Applicant: LAM RESEARCH CORPORATION, Fremont, CA (US)

(72) Inventors: Richard BLANK, San Jose, CA (US); Roy Scott POWELL, Campbell, CA (US)

(21) Appl. No.: 18/880,670

(22) PCT Filed: Jun. 27, 2023
(86) PCT No.: PCT/US2023/026279

§ 371 Date: Jan. 2, 2025

Related U.S. Application Data
(60) Provisional application No. 63/358,352, filed on Jul. 5, 2022.

(51) Int. Cl. H01L 21/67; B25J 11/00; B25J 15/00; B25J 19/02; H01L 21/687

(52) U.S. Cl. CPC H01L 21/67248; B25J 11/0095; B25J 15/0014; B25J 19/02; H01L 21/68707

(57) ABSTRACT

An end effector for supporting a wafer, the end effector having a temperature sensor that is configured to sense a temperature of a wafer supported by the end effector.

### CROSS-REFERENCE TO RELATED APPLICATIONS

This application claims the benefit of U.S. Provisional Application No. 63/358,352 filed on Jul. 5, 2022. The entire disclosure of the above application is incorporated herein by reference.

### FIELD OF THE INVENTION

The present invention relates to an end effector, and specifically to an end effector that has a temperature sensor.

### BACKGROUND OF THE INVENTION

Microelectronic devices are fabricated on semiconductor (e.g. silicon) wafers using a variety of techniques, including deposition techniques and removal techniques. Semiconductor wafers may be further treated in ways that alter their mass, e.g. by cleaning, ion implantation, lithography and the like.

Measuring the change in mass of a wafer either side of a processing step is an attractive method for implementing product wafer metrology. It is relatively low cost, high speed and can accommodate different wafer circuitry patterns automatically. In addition, it can often provide results of higher accuracy than alternative techniques. The wafer in question is weighed before and after the processing step of interest. The change in mass is correlated to the performance of the production equipment and/or the desired properties of the wafer.

Processing steps carried out on semiconductor wafers can cause very small changes in the mass of the semiconductor wafer, which it may be desirable to measure with high accuracy. For example, removing a small amount of material from the surface of the semiconductor wafer may reduce the mass of the semiconductor wafer by a few milligrams, and it may be desirable to measure this change with a resolution of the order of ±100 μg or better.

At these high levels of measurement accuracy, errors in the measurement output caused by temperature variations in the semiconductor wafers being measured and/or in the temperature of the measurement apparatus may become significant. For example, a temperature difference of approximately 0.005° C. between the semiconductor wafer and the measurement balance or enclosure may cause an error of approximately 5 μg in the determined mass of the semiconductor wafer.

For example, if the semiconductor wafer has a higher temperature than a measurement chamber of the measurement apparatus, air currents (e.g. convection currents) may be generated in the air in the measurement chamber, which may affect the measurement output. In addition, the air in the measurement chamber may be heated, changing its density and pressure and therefore the buoyancy force exerted on the semiconductor wafer by the air. This may also affect the measurement output.

The temperature of a semiconductor wafer immediately after it has been processed in a production line may be 400-500° C. or higher. After processing the semiconductor wafer may be loaded into a Front Opening Unified Pod (FOUP) together with other recently processed semiconductor wafers for transportation between different processing locations of the production line. When the FOUP arrives at a weighing device for weighing the semiconductor wafers, the temperature of the semiconductor wafers may still be high, for example 70° C. or higher. In contrast, the temperature of the weighing device may be approximately 20° C. Therefore, there may be a significant temperature difference between the semiconductor wafers and the weighing device.

WO02/03449, the whole contents of which are incorporated herein by reference, describes a semiconductor wafer mass metrology method that aims to reduce errors in the measurement output caused by temperature variations in the measurement balance or the semiconductor wafers being measured. In the method described in WO02/03449, a semiconductor wafer is removed from a FOUP and placed on a passive thermal transfer plate that is thermally coupled to a chamber of a weighing apparatus before it is placed on a measurement area of the weighing apparatus. The passive thermal transfer plate equalises the temperature of the semiconductor wafer to the temperature of the chamber to within ±0.1° C.

WO2015/082874, the whole contents of which are incorporated herein by reference, describes a development of the semiconductor wafer mass metrology method described in WO02/03449, wherein a bulk of the heat load is removed from the semiconductor wafer before using the thermal transfer plate to equalise the temperature of the semiconductor wafer to the temperature of the semiconductor wafer mass metrology apparatus, to reduce the heat load on the semiconductor wafer mass metrology apparatus (which may otherwise cause changes in the temperature of the semiconductor wafer mass metrology apparatus).

In an embodiment disclosed in WO2015/082874, the bulk of the heat load is removed from the semiconductor wafer using an active thermal transfer plate in which the heat load is actively dissipated using thermoelectric devices, and then the temperature of the semiconductor wafer is subsequently equalised to the temperature of the measurement chamber using a passive thermal transfer plate that is mounted on an upper surface of the measurement chamber and in thermal equilibrium with the measurement chamber.

WO2020/064470, the whole contents of which are incorporated herein by reference, discloses that an amount of time taken to change the temperature of a semiconductor wafer using a thermal transfer plate, for example an active thermal transfer plate, can be reduced by taking into account the initial incoming temperature of the semiconductor wafer when subsequently performing the cooling or heating of the semiconductor wafer, for example so that cooler semiconductor wafers are not cooled for as long as hotter semiconductor wafers, or for example so that a semiconductor wafer is not cooled at all if its temperature is already equal to, or within a predetermined range of, a predetermined temperature. Therefore, the throughput and productivity of semiconductor wafer processing may be improved.

In particular, WO2020/064470 discloses detecting information relating to the temperature of the semiconductor wafer, and controlling a duration of cooling or heating of the semiconductor wafer based on the detected information relating to the temperature of the semiconductor wafer. In the embodiments of WO2020/064470, the temperature of the wafer is detected using an IR sensor of the apparatus.

### SUMMARY OF THE INVENTION

The present inventors have investigated methods of detecting the temperature of a wafer, for example an initial or incoming temperature of a wafer before subsequently performing heating or cooling of the wafer, that do not significantly impact on wafer throughout.

The present inventors have realised that a temperature of the wafer can be detected while it is being supported by an end effector using a temperature sensor of the end effector.

Therefore, the temperature of the wafer can be detected during transportation of the wafer using the end effector, for example while the wafer is being transported from a wafer container to a temperature changing part or a measurement part of an apparatus. As such, wafer throughput is not significantly affected by the temperature measurement.

At its most general, the present invention therefore relates to sensing a temperature of a wafer using a temperature sensor of an end effector that is used to support the wafer.

According to a first aspect of the present invention, there is provided an end effector for supporting a wafer, the end effector having a temperature sensor that is configured to sense a temperature of a wafer supported by the end effector.

The first aspect of the present invention may have any one, or, where compatible, any combination of the following optional features.

At its most general, an end effector may be a support for supporting the wafer, for example while the wafer is being moved or transported.

The end effector may be referred to as a robot end effector, or a robot arm end effector, for example.

Typically, the end effector is used to support the wafer while the wafer is being moved or transported by the end effector.

The end effector may be configured or adapted to support the wafer.

The end effector may be configured or adapted to support the wafer from beneath the wafer.

The end effector may comprise a support surface that is configured to contact an underside of the wafer to support the wafer from beneath.

The end effector may comprise a blade for supporting the wafer from beneath.

The end effector may comprise a body having a flat, or substantially flat, upper surface. The upper surface of the body is a surface of the body that faces toward the wafer when the wafer is supported by the end effector.

The end effector may be plate-like.

The end effector may be elongate.

The body may be plate-like.

The body may be elongate.

The end effector may comprise one or more contact or support elements or parts that are configured to contact an underside of the wafer to support the wafer from beneath.

The end effector may be configured to be attached, or mounted, on or to a robot arm or robotic arm.

The wafer may be a semiconductor wafer, for example a silicon wafer.

Supporting the wafer may mean supporting the weight of the wafer, and/or carrying the wafer, and/or holding the wafer.

The end effector may comprise a mechanism, means or device for gripping or holding the wafer while it is supported from beneath, for example a vacuum clamp or vacuum grip or an edge grip.

For example, the end effector may comprise one or more vacuum pads that are connectable to a source of vacuum/low-pressure and that are configured to apply a vacuum/low-pressure to the wafer to hold the wafer.

Alternatively, the end effector may comprise one or more movable plungers or parts that are configured to push the edge of the wafer against a corresponding stop so as to grip the edge of the wafer.

The end effector may be a friction end effector.

The end effector may prevent or restrict lateral movement of the wafer relative to the end effector by friction between the end effector and the wafer.

The end effector may comprise one or more pads configured to increase friction between the end effector and the wafer. For example, the one or more pads may comprise a material having a higher coefficient of friction with the wafer than a main material of the end effector.

A temperature sensor may mean a device that senses, detects or measures a temperature.

The temperature sensor may instead be referred to as a temperature detector, or a temperature measuring device.

The temperature sensor sensing a temperature typically means that an output of the temperature sensor varies or changes depending on the temperature.

Typically, an output of the temperature sensor depends on, or corresponds to, the temperature.

The temperature sensor may output an electrical signal that depends on, or corresponds to, the temperature.

The temperature sensor may be positioned and/or arranged and/or adapted to sense the temperature of the wafer supported by the end effector.

The temperature sensor may be configured to sense a temperature of an underside of the wafer.

The end effector may comprise the temperature sensor.

The temperature sensor may be configured to be in thermal contact with a wafer supported by the end effector.

The temperature sensor may be configured and/or positioned and/or arranged and/or adapted to be in thermal contact with a wafer supported by the end effector, either directly or indirectly via an intermediate part, component or material.

The temperature sensor may comprise a thermocouple.

The temperature sensor may be in, or inside, or at least partially in, or at least partially inside, the end effector.

The temperature sensor may be embedded, or partially embedded, in the end effector. The temperature sensor may be at least partially embedded in the end effector.

The temperature sensor may be embedded, or partially embedded, in a body of the end effector. The temperature sensor may be at least partially embedded in the body of the end effector. The body may be a main body.

The temperature sensor may be embedded, or partially embedded, in a contact part or support part of the end effector.

The end effector may comprise a plurality of pads that are configured to support the wafer, and the temperature sensor may be embedded, or partially embedded, in one of the pads.

The pads may be configured to contact the wafer to support the wafer.

The pads may instead be referred to as wafer contact parts, or wafer support parts, for example.

The pads may extend upwards from an upper surface of the end effector, so as to contact the wafer and support the wafer above the upper surface of the end effector.

The pads may be provided in or on an upper surface of the end effector, for example an upper surface of a main body of the end effector.

The pads may be configured to support the wafer from underneath by contacting an underside of the wafer.

There may be three of the pads, or three or more of the pads, for example.

The other pad or pads (i.e. the pads not having the temperature sensor) may be configured to increase friction between the end effector and the wafer. For example, the other pad or pads may comprise a material having a higher coefficient of friction with the wafer than a main material of the end effector.

For example, the other pad or pads may comprise a polymer.

The temperature sensor being embedded, or partially embedded, in the pad may mean that the temperature sensor is in or inside, or at least partially in or inside, the pad.

The temperature sensor may be at least partially positioned in a hole, opening, void, bore or passageway in the end effector, for example in a main body of the end effector.

The end effector may comprise a main body having a through hole, and the temperature sensor may be located, or partially located, in the through hole.

The through hole extends from an underside of the main body to the upper side of the main body.

Used herein, the upper side of the main body refers to a side of the main body that is used to support the wafer and/or that faces the wafer when the wafer is supported by the end effector, and the underside of the main body refers to an opposite side of the main body.

The end effector may comprise a tubular part located in the through hole.

For example, the tubular part may cover, or substantially cover, an inner circumferential surface of the through hole.

An outer surface of the tubular part may be in contact, for example direct contact, with an inner circumferential surface of the through hole.

The tubular part may surround, or partially surround, the temperature sensor, which is located, or partially located, in the through hole.

The tubular part has a central hole, or bore, or passageway in which the temperature sensor is located or partially located.

The tubular part may comprise a material having a lower thermal conductivity than a material of the main body of the end effector.

The material of the main body of the end effector may be aluminium, stainless steel, or a ceramic, for example.

The material having the lower thermal conductivity may comprise polyoxymethylene.

However, other materials may be used instead of polyoxymethylene, for example Polyetheretherketone or Polyethylene terephthalate.

The end effector may comprise a cap or cover on an upper side of the tubular part.

The cap or cover therefore covers an upper end of the through hole.

At least a top surface of the cap or cover may be raised up above the surrounding upper surface of the main body of the end effector.

The cap or cover may therefore protrude or extend upwards above the upper surface of the main body of the end effector.

For example, this may be achieved by the tubular part extending upwards above the surrounding upper surface of the main body of the end effector.

Therefore, the top surface of the cap or cover may come into direct contact with a wafer when the wafer is supported by the end effector. The top surface of the cap or cover may support or partially support the wafer. The top surface of the cap or cover may therefore be configured to contact and support a wafer received by the end effector.

The cap or cover may comprise a material having a higher thermal conductivity than the material of the tubular part.

The material having the higher thermal conductivity may comprise Aluminium.

The temperature sensor may be attached to an underside of the cap or cover.

The underside of the cap or cover means a side that faces the through hole in the main body of the end effector.

Therefore, when a wafer is supported by the end effector, the wafer may come into contact with the cap or cover, and there may be good thermal contact between the temperature sensor and the wafer via the cap or cover.

The temperature sensor may be attached to the underside of the cap or cover using a thermally conductive adhesive, for example thermal epoxy.

The end effector may comprise a controller that is configured to receive an output of the temperature sensor.

The controller may be a microcontroller.

The controller may be electrically connected to the temperature sensor, for example by one or more wires.

The controller may be configured to calculate a temperature based on the output of the temperature sensor.

The controller may be configured to calculate the temperature using a calibration algorithm.

Alternatively, the end effector may be configured to output the output of the temperature sensor to a device or apparatus connected to the end effector, such as a robotic arm, and the temperature may be measured or calculated elsewhere based on the output of the temperature sensor. The end effector may therefore comprise one or more wires or connectors for communicating an output of the temperature sensor to a device or apparatus connected to the end effector. In this case, the controller may not be required and may not be present.

The temperature sensor may be configured to continuously sense the temperature of the wafer and to provide an output to the controller.

Alternatively, the controller may control the temperature sensor to perform a measurement at a particular point of time.

According to a second aspect of the present invention there is provided a robotic arm having the end effector according to the first aspect of the present invention.

The end effector in the second aspect of the present invention may have any one, or, where compatible, any combination of the features of the end effector of the first aspect of the present invention described above or below.

The robotic arm may be part of a robot and/or connected to a robot.

The robotic arm may be configured to move the end effector.

The robotic arm may be configured to move or transport a wafer using the end effector.

According to a third aspect of the present invention there is provided an apparatus comprising:
a cooling or heating part for cooling or heating a wafer; and
the end effector according to the first aspect of the present invention, wherein the apparatus is configured to use the end effector to transport the wafer to the cooling or heating part.

The end effector in the third aspect of the present invention may have any one, or, where compatible, any combination of the features of the end effector of the first aspect of the present invention described above or below.

The apparatus according to the third aspect of the present invention may have any one, or, where compatible, any combination of the following optional features.

The cooling or heating part may be a cooling or heating device.

The cooling or heating part may be a passive cooling or heating part, such as a passive thermal transfer plate.

In this context, “passive” means that the cooling or heating part is neither cooled nor heated by cooling/heating elements, but rather receives its temperature by the surrounding ambient environment only.

A passive thermal transfer plate is typically a plate or block of material having a high thermal mass and/or high thermal conductivity.

For example, a passive thermal transfer plate may be a plate or block of metal, such as aluminium.

Alternatively, the cooling or heating part may be an active cooling or heating part, such as an active thermal transfer plate.

In this context, “active” means that the cooling or heating device is heated or cooled by a powered heating or cooling device.

An active thermal transfer plate may comprise a plate or block of material having a high thermal mass and/or high thermal conductivity that is heated or cooled by one or more powered cooling or heating devices. For example, the plate or block of material may be a plate or block of metal, such as aluminium that is heated or cooled using one or more Peltier devices.

The apparatus may further comprise a robotic or robot arm having the end effector.

The apparatus may be configured to use the end effector to transport a wafer from a wafer container, such as a FOUP, to the cooling or heating part.

The apparatus may also be configured to use the end effector to subsequently pick up the wafer from the cooling or heating part. Alternatively, a different end effector may be used to pick up the wafer from the cooling or heating part.

The apparatus may further comprise a controller that is configured to control a duration of cooling or heating of the wafer by the cooling or heating part based on an output of the temperature sensor when the end effector was being used to transport the wafer.

For example, based on an output of the temperature sensor obtained when the end effector was being used to transport the wafer, the controller may control the duration of subsequent cooling or heating of the wafer by the cooling or heating part so that when cooling a wafer, a hotter wafer is cooled for longer than a cooler wafer, or so that when heating a wafer, a cooler wafer is heated for longer than a hotter wafer.

The controller may be configured to control a duration of cooling or heating of the wafer to be zero when a temperature sensed by the temperature sensor is equal to, or within a predetermined range of, a predetermined temperature.

The controller may be configured to skip an available cooling or heating step if a temperature difference between a temperature sensed by the temperature sensor and a predetermined temperature is less than ±2K, or ±1K, or ±0.5K, or ±0.1K.

The temperature sensor of the end effector may be used to detect an initial or incoming temperature of the wafer, for example a temperature of the semiconductor wafer soon, or (immediately) before the cooling or heating of the semiconductor wafer will be started if cooling or heating of the semiconductor wafer is performed. For example, the temperature of the semiconductor wafer may be measured less than 1 minute, or less than 30 seconds, or less than 10 second before the cooling or heating of the semiconductor wafer will be started if cooling or heating of the semiconductor wafer is performed.

The temperature of the semiconductor wafer may be measured less than three seconds before the cooling or heating of the semiconductor wafer will be started, if cooling or heating of the semiconductor wafer is to be performed, for example less than three seconds before the wafer will be placed on a thermal transfer plate. Then, the measured temperature accurately corresponds to the temperature of the semiconductor wafer when the cooling or heating of the semiconductor wafer will be started, if cooling or heating of the semiconductor wafer is performed.

The apparatus is configured to use the end effector to transport the wafer to the cooling or heating part. For example, the apparatus may be configured to control the end effector to pick up a wafer located in a wafer container such as a FOUP. The apparatus may then be configured to control the end effector to transport the wafer from the wafer container to the cooling or heating part and to load the wafer on to the cooling or heating part (unless the cooling or heating is to be skipped). The apparatus may be further configured to control the end effector to sense a temperature of the wafer using the temperature sensor while the end effector is transporting the wafer from the wafer container to the cooling or heating part. As mentioned above, the output of the temperature sensor can then be used to control a duration of the subsequent cooling or heating of the wafer by the cooling or heating part.

The apparatus may be a wafer mass metrology apparatus that further comprises a measurement area.

The measurement area may comprise a weighing device.

The measurement area may further comprise a weighing chamber that encloses the weighing device.

The weighing device may comprise a weighing pan on which the wafer is loaded.

The apparatus may be configured to calculate a mass of the wafer based at least on a measurement output of the weighing device.

According to a fourth aspect of the present invention there is provided a method comprising:
supporting a wafer using an end effector; and
sensing a temperature of the wafer using a temperature sensor of the end effector.

The fourth aspect of the present invention may include any one, or, where compatible, any combination of the features of the first to third aspects of the present invention described above or below.

The fourth aspect of the present invention may include any one, or, where compatible, any combination of the following optional features.

The method may further comprise controlling a duration of cooling or heating of the wafer based on an output of the temperature sensor. In particular, the method may comprise using an output of the temperature sensor obtained when the end effector was supporting the wafer to control a duration of subsequent cooling or heating of the wafer.

The method may comprise controlling a duration of cooling or heating of the wafer to be zero when a temperature sensed by the temperature sensor is equal to, or within a predetermined range of, a predetermined temperature.

The method may comprise skipping an available cooling or heating step if a temperature difference between a temperature sensed by the temperature sensor and a predetermined temperature is less than +2K, or +1K, or +0.5K, or +0.1K.

The method may be a wafer mass metrology method, and the method may further comprise subsequently loading the wafer onto a measurement area of a wafer mass metrology apparatus.

The invention includes the combination of the aspects and preferred features described except where such a combination is clearly impermissible or expressly avoided.

### BRIEF DESCRIPTION OF THE DRAWINGS

Embodiments of the present invention will now be discussed, by way of example only, with reference to the accompanying Figures, in which:

FIG. 1 is a schematic top view of an end effector according to a first embodiment of the present invention;

FIG. 2 is a schematic top view of the end effector according to the first embodiment of the present invention with a wafer supported by the end effector;

FIG. 3 is a schematic side view of the end effector according to the first embodiment of the present invention;

FIG. 4 is a schematic side view of the end effector according to the first embodiment of the present invention with a wafer supported by the end effector;

FIG. 5 is a schematic partial cross-sectional view of the end effector according to the first embodiment of the present invention;

FIG. 6 is a schematic top view of a robotic arm according to a second embodiment of the present invention;

FIG. 7 is a schematic illustration of a semiconductor wafer mass metrology apparatus according to a third embodiment of the present invention;

FIG. 8 is a schematic illustration of a semiconductor wafer mass metrology apparatus according to a fourth embodiment of the present invention; and

FIG. 9 is a schematic illustration of a semiconductor wafer mass metrology apparatus according to a fifth embodiment of the present invention.

### DETAILED DESCRIPTION OF THE PREFERRED EMBODIMENTS AND FURTHER OPTIONAL FEATURES OF THE INVENTION

Aspects and embodiments of the present invention will now be discussed with reference to the accompanying figures. Further aspects and embodiments will be apparent to those skilled in the art. All documents mentioned in this text are incorporated herein by reference.

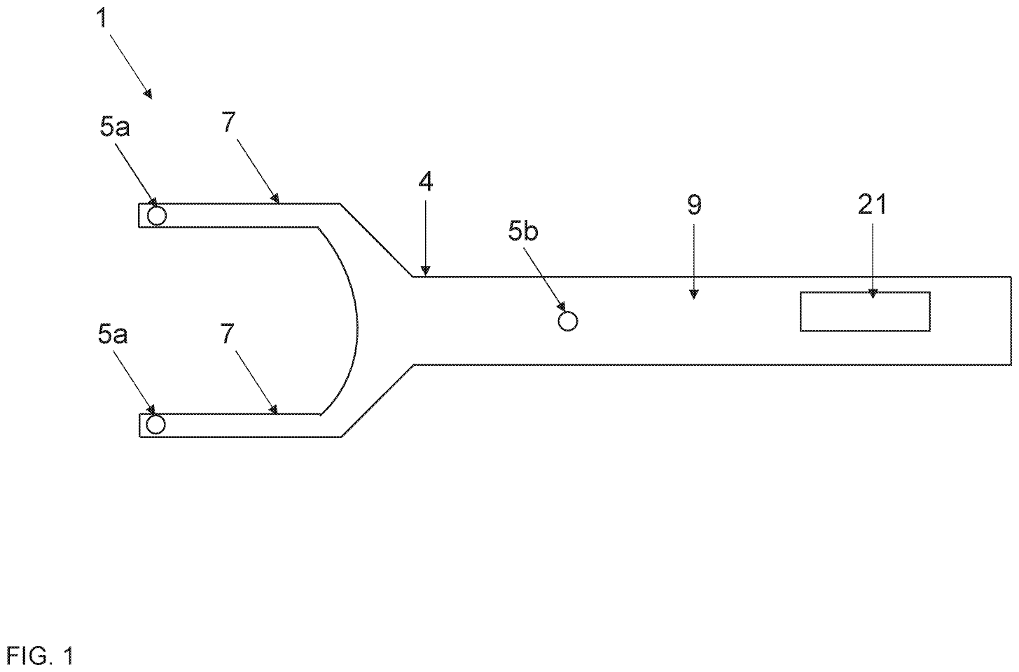

An end effector 1 according to a first embodiment of the present invention will be described with reference to FIGS. 1 to 5.

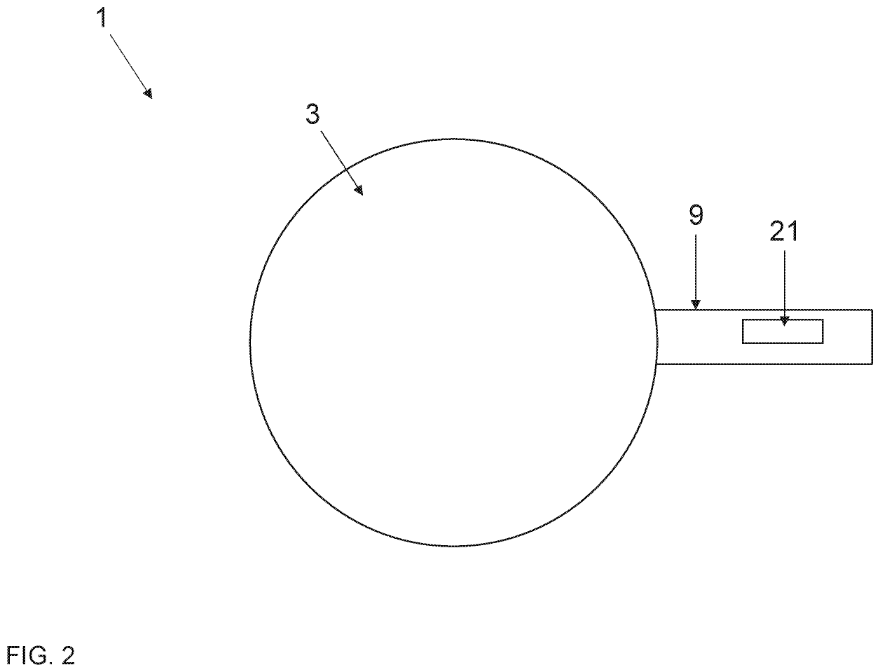

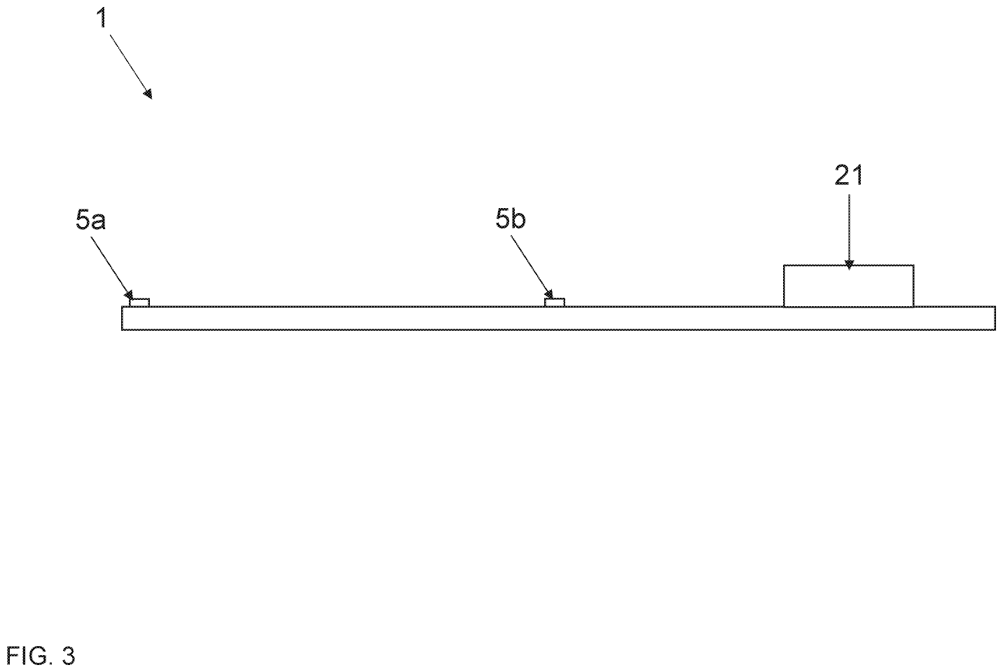

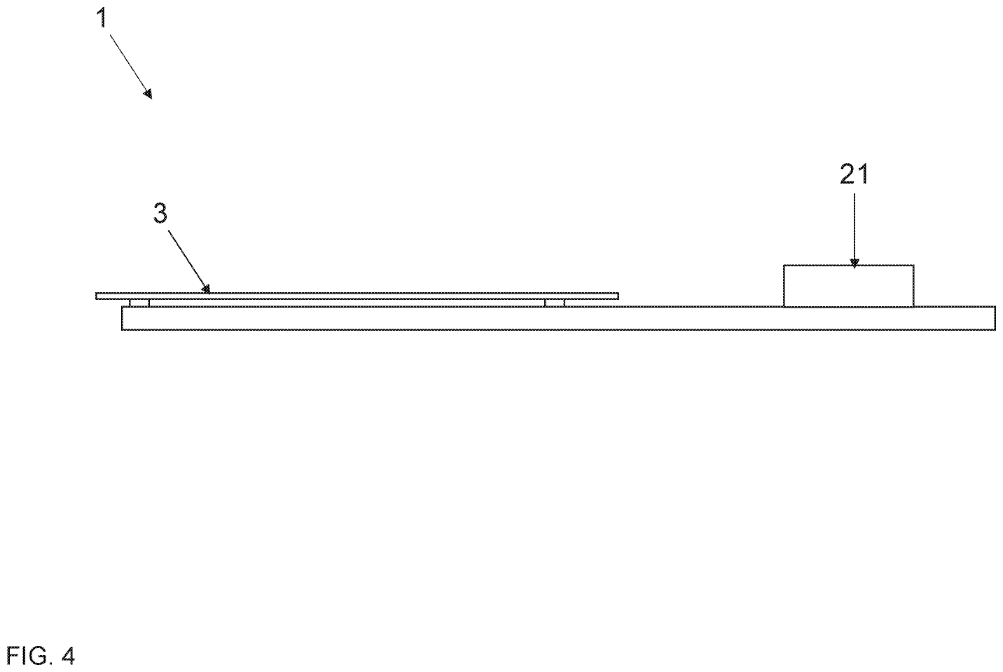

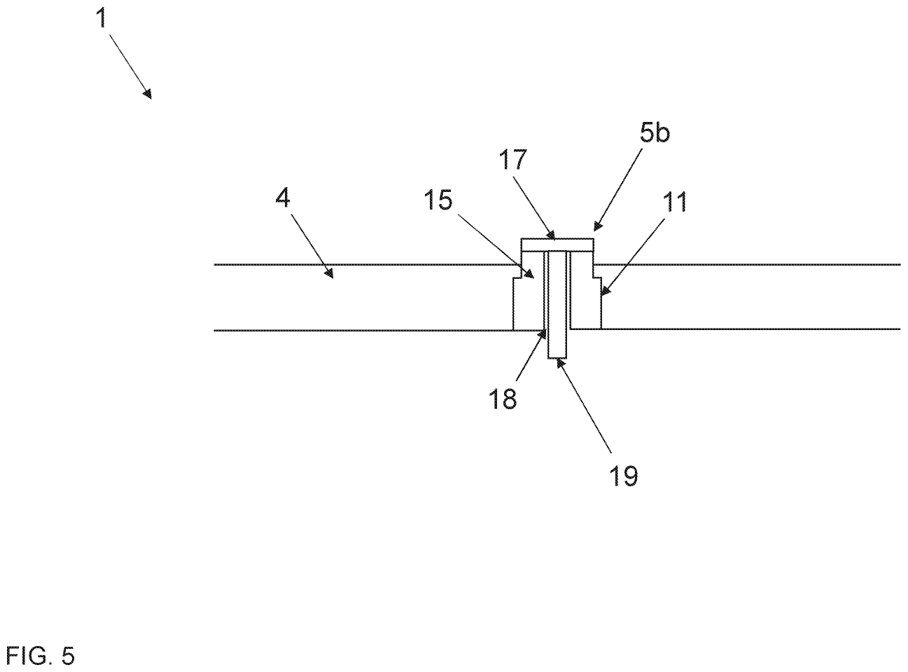

FIG. 1 is a schematic top view of the end effector 1, FIG. 2 is a schematic top view of the end effector 1 with a wafer 3 supported by the end effector 1, FIG. 3 is a schematic side view of the end effector 1, FIG. 4 is a schematic side view of the end effector 1 with a wafer 3 supported by the end effector 1, and FIG. 5 is a schematic partial cross-sectional view of the end effector 1.

As shown in FIGS. 1 to 4, the end effector 1 is configured to support the wafer 3 from beneath the wafer 3. In particular, the end effector 1 is configured to contact an underside of the wafer 3 to support the wafer 3 from beneath the wafer 3.

A main body 4 of the end effector 1 has a flat or substantially flat upper surface. The upper surface of the main body 4 is a surface of the main body 4 that faces toward the wafer 3 when the wafer is supported by the end effector 1.

The main body 4 is elongate, and a thickness of the main body 4 perpendicular to the upper surface is significantly less than a length or width of the main body 4.

The main body 4 may be plate-like, for example.

The main body 4 may be referred to as a blade, for example.

The end effector 1 comprises three pads 5a and 5b that are configured to contact the underside of the wafer 3 to support the wafer 3 from beneath. The pads 5a and 5b may be referred to as wafer contact pads, or wafer support pads, for example.

The three pads 5a are provided in or on the upper surface of the main body 4 of the end effector 1.

The three pads 5a and 5b protrude or extend upwards from the upper surface of the main body 4, so as to contact the underside of the wafer 3 and support the wafer 3 above the upper surface of the main body 4.

Each of the three pads 5a and 5b protrudes or extends above the upper surface of the main body 4 by a same amount, so as to support the wafer 3 parallel to the upper surface of the main body 4.

As shown in FIG. 1, for example, a distal end of the main body 4 has a pronged or fork-like shape comprising two prongs or forks 7.

The distal end of the main body 4 is connected to, or integral with, a shaft 9 of the main body 4. In this embodiment, the shaft 9 is rectangular.

As shown in FIG. 1, for example, the main body 4 of the end effector 1 therefore comprises a shaft 9 and two prongs or forks 7 at a distal end of the shaft 9.

A respective one of the pads 5a is located in or on an upper surface of each of the two prongs or forks 7. A third one of the pads 5b is located in or on an upper surface of the shaft 9.

A configuration of the pad 5b is different to a configuration of the pads 5a, as discussed below. The configurations of the pads 5a may be the same or different.

The pads 5a may be configured to increase friction between the end effector 1 and the wafer 3, so as to restrict or prevent lateral movement of the wafer 3 relative to the end effector 1 while the wafer 3 is being carried by the end effector 1.

For example, the pads 5a may comprise or be made of a material having a higher coefficient of friction with the wafer 3 than a main material of the end effector 1. For example, a main material of the end effector 1 may be aluminium, stainless steel or ceramic.

The end effector 1 may therefore be considered to be a friction end effector.

The pads 5a may be made from or comprise one or more polymers.

Of course, in other embodiments a different number of pads may be provided, and/or the pads may be in different positions. In general, the end effector 1 will comprise three or more pads.

In addition, in other embodiments the pads 5a and 5b may be omitted, so that the wafer 3 is directly supported by the upper surface of the main body 4 of the end effector 1.

In addition, in other embodiments the end effector 1 may have a different shape and/or configuration to that illustrated in FIGS. 1 to 4. For example, in other embodiments a number of the prongs or forks 7 may be different, or the prongs or forks 7 may not be provided.

FIG. 5 is a schematic partial cross-sectional view of the end effector 1. In particular, FIG. 5 is a partial cross-sectional view through the pad 5b of the end effector 1.

As shown in FIG. 5, the end effector 1 comprises a through hole 11 through the main body 4 of the end effector 1. In particular, the through hole 11 extends from a lower surface of the main body 4 to the upper surface of the main body 4.

A tubular part 15 is located in the through hole with an outer surface of the tubular part 15 in contact with an inner surface of the through hole 11. The tubular part 15 comprises (or is made of) a low thermal conductivity material, such as polyoxymethylene. The inner surface of the through hole 11 is therefore covered by the low thermal conductivity material.

The material being low thermal conductivity material means that the material has a lower thermal conductivity than a material of the main body 4 of the end effector 1. A material of the main body 4 may be aluminium, or stainless steel, or a ceramic, for example.

The tubular part 15 may be in the form of a tube, ring, annulus, or sleeve, for example.

As shown in FIG. 5, the tubular part 15 extends along a whole length of the through hole 11.

A cap or cover 17 is provided on an upper side of the tubular part 15. The cap or cover 17 therefore covers a top surface of the through hole 11.

The cap or cover 17 comprises (or is made of) a high thermal conductivity material, such as Aluminium. The cap or cover 17 is attached or connected to the top of the tubular part 15.

The material being a high thermal conductivity material means that the material has a higher thermal conductivity than the material of the tubular part 15.

At least a top surface of the cap or cover 17 is raised up above the surrounding upper surface of the main body 4 of the end effector 1.

For example, this may be achieved by the tubular part 15 extending upwards above the surrounding upper surface of the main body 4 of the end effector 1, as illustrated in FIG. 5.

The tubular part 15 surrounds a hole 18 that extends from the lower surface of the main body 4 of the end effector 1 to an underside of the cap or cover 17. The hole 18 is part of the through hole 11.

A thermocouple 19 is inserted into the hole 18 from the underside of the main body 4 of the end effector 1, so that the thermocouple is at least partially located inside the hole 18. The thermocouple 19 is therefore also at least partially located in the through hole 11.

The thermocouple 19 is attached to a bottom of the cap or cover 17, for example using a thermal adhesive such as thermal epoxy.

When a wafer 3 is supported by the end effector 1, with the wafer 3 supported by the pads 5a and 5b, the thermocouple 19 is in thermal contact with the wafer 3 via the cap or cover 17. Since the cap or cover 17 is made of high thermal conductivity material, there is a good thermal contact between the wafer 3 and the thermocouple 19 via the cap or cover 17.

In particular, the cap or cover 17 is configured to come into contact with the wafer and to support the wafer 3 when the wafer 3 is received and supported by the end effector 1.

Therefore, the thermocouple 19 is configured to sense a temperature of the wafer 3 supported by the end effector 1.

The pad 5b may be considered to correspond to the cap or cover 17.

Alternatively, the pad 5b may be considered to correspond to the cap or cover 17 and the tubular part 15.

Alternatively, the pad 5b may be considered to correspond to the cap or cover 17, the tubular part 15 and the thermocouple 19.

The pad 5b may be inserted into the through hole 11 from the underside of the main body 4 of the end effector 1.

The pad 5b may be located, or at least partially located, inside the through hole 11.

As shown in FIG. 5, the inner circumferential surface of the through hole 11 includes a step at which a diameter of the through hole 11 is reduced when moving from the lower surface to the upper surface of the main body 4.

An outer surface of the tubular part 15 has a corresponding or complementary step, at which a diameter of the outer surface of the tubular part 15 is reduced when moving from the lower surface to the upper surface of the main body 4. The step of the tubular part 15 is configured to contact and abut against the step of the inner circumferential surface of the through hole 11 when the tubular part 15 is inserted into the through hole 11, to limit the extent to which the pad 5b can be inserted into the through hole 11.

The thermocouple 19 may be in, for example located in, or embedded in, or inside, the support pad 5b.

As shown in FIGS. 1 to 3, the end effector 1 comprises a microcontroller 21 that is configured to receive an output of the thermocouple 19. In particular, the microcontroller 21 is electrically connected to the thermocouple 19, for example by one or more wires.

The microcontroller 21 is configured to calculate and/or measure the temperature of the wafer 3 based on the output of the thermocouple 19.

The microcontroller 21 may be configured to calculate and/or measure the temperature of the wafer 3 using a predetermined calibration algorithm.

For example, the predetermined calibration algorithm may be determined in advance by measuring the output of the thermocouple 19 for different known temperatures sensed by the thermocouple, so as to determine a relationship between the output of the thermocouple 19 and the temperature being sensed.

The known temperature may be determined using an alternative temperature sensor, or by controlling the temperature to be a predetermined temperature using a heating or cooling device.

The predetermined calibration algorithm may be stored in a memory of the microcontroller.

Of course, in other embodiments there may be more than one pad having a temperature sensor. In addition, or alternatively, one or both of the pads 5a may have a temperature sensor.

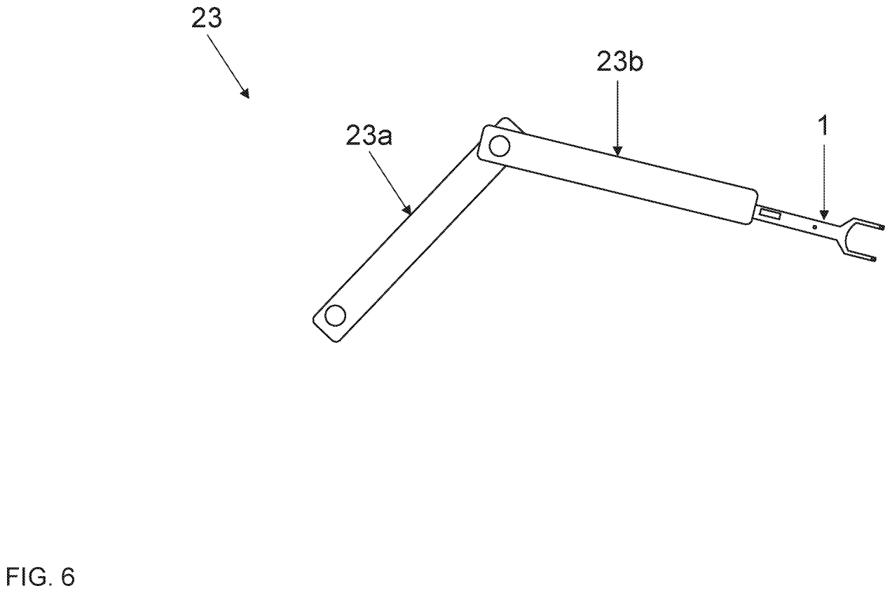

FIG. 6 shows a robotic arm 23 according to a second embodiment of the present invention. The robotic arm 23 has the end effector 1 according to the first embodiment of the present invention.

The end effector 1 may be considered to be part of the robotic art 23, or the combination of the robotic arm 23 and the end effector 1 may comprise a robot.

The end effector 1 is attached, connected or mounted on or to the robotic arm 23. The attachment, connection or mounting may be fixed, so that the orientation of the end effector 1 is fixed relative to the robotic arm 23, or may be rotary or pivotal, so that the end effector 1 can be rotated or pivoted relative to the robotic arm 23.

In this embodiment, the robotic arm 23 comprises two arm sections 23a and 23b that are connected together at respective ends thereof by a rotary or pivot connection, so that the arm section 23b can be rotated relative to the arm section 23a.

The end effector 1 is attached, connected or mounted at a distal end of the arm section 23b.

The first arm section 23a may be rotatably or pivotably mounted at a proximal end thereof, so that the whole robotic arm 23 can be rotated or pivoted.

Of course, the robotic arm 23 in FIG. 6 is merely one example of a robotic arm according to a second embodiment of the present invention, and many different types of robotic arm can be used in the present invention.

The robotic arm 23 may comprise a microcontroller or processor for receiving an output of the microcontroller 21 of the end effector 1.

Alternatively, or in addition, the robotic arm 23 may comprise one or more wires or connections for transferring an output of the microcontroller 21 of the end effector 1 to a further device or apparatus to which the robotic arm 23 is connected, or with which the robotic arm 23 is in communication.

There may be a serial connection or communication between the robotic arm 23 and the microcontroller 21 of the end effector 1.

As discussed below, the temperature of the wafer 3 calculated or measured by the microcontroller 21 based on the output of the thermocouple 9 is used in embodiments of the present invention to control a duration of cooling or heating of the wafer 3, for example before the wafer is loaded onto a measurement area of a measurement apparatus.

Alternatively, an output of the thermocouple 9 may be communicated to an outside of the end effector 1, for example to a controller in the robotic arm 23 or an apparatus, and the temperature of the wafer may be calculated there instead of by a microcontroller 21 of the end effector 1.

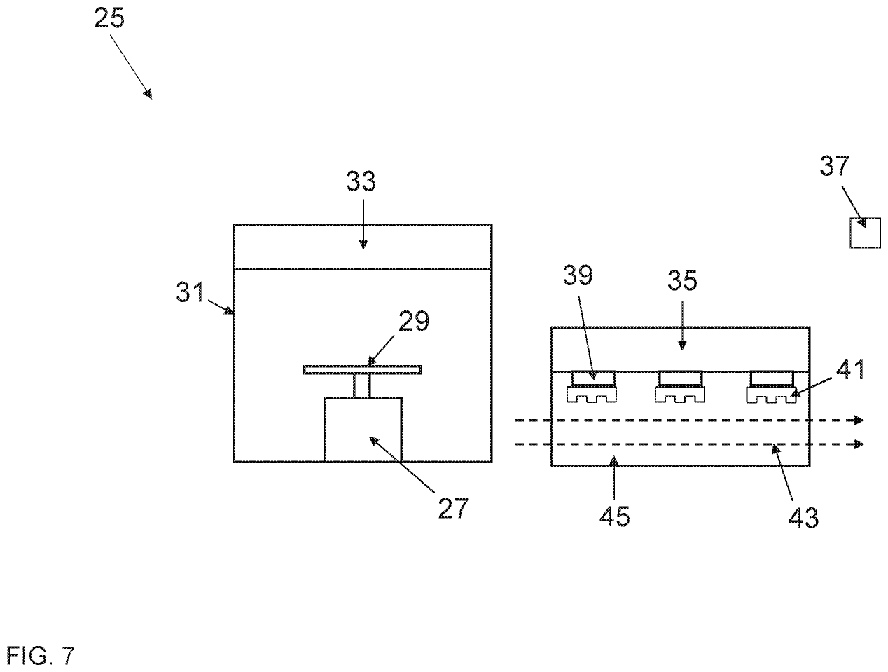

FIG. 7 shows a semiconductor wafer mass metrology apparatus 25 according to a third embodiment of the present invention.

In the third embodiment of the present invention, the end effector 1 of the first embodiment of the present invention is used to transport a semiconductor wafer, as discussed below.

The third embodiment of the present invention may include the robotic arm 23 of the second embodiment of the present invention for transporting a semiconductor wafer, as discussed below, or another robotic arm.

The semiconductor wafer mass metrology apparatus 25 comprises a weighing balance 27 having a weighing pan 29 for receiving a semiconductor wafer. The weighing balance 27 is configured to provide measurement output indicative of the weight of a semiconductor wafer loaded on the weighing pan 29.

The weighing balance 27 is located within a weighing chamber 31, which forms an enclosed environment around the weighing balance 27, for example to maintain a substantially uniform air density and/or air pressure and/or air temperature around the weighing balance 27.

The weighing chamber 31 has an opening, e.g. a suitably sized slot in a side-wall of the weighing chamber 31, to allow a semiconductor wafer to be transported into the weighing chamber 31 and positioned on the weighing pan 29. When not in use, the opening may be covered by an openable door or covering to allow the weighing chamber 31 to be substantially closed or sealed when performing measurements using the weighing balance 27. The semiconductor wafer may be transported into the weighing chamber 31 and positioned on the weighing pan 29 using a robotic arm having an end effector for supporting the semiconductor wafer. The end effector may be the end effector 1 of the first embodiment of the present invention.

A passive thermal transfer plate 33 is positioned on top of the weighing chamber 31. The passive thermal transfer plate 33 comprises a block of material having a good thermal conductivity (for example Aluminium).

The passive thermal transfer plate 33 is positioned directly on top of the weighing chamber 31, so that there is a good thermal contact between the passive thermal transfer plate 33 and the weighing chamber 31. The passive thermal transfer plate 33 is in direct physical contact with the weighing chamber 31. The passive thermal transfer plate 33 may be attached or fixed to the weighing chamber 31, for example using one or more bolts (not shown) and/or a thermally conductive bonding layer (not shown).

As a result of the good thermal contact between the passive thermal transfer plate 33 and the weighing chamber 31, the passive thermal transfer plate 33 may be substantially in thermal equilibrium with the weighing chamber 31 and therefore may have substantially the same temperature as the weighing chamber 31.

Therefore, when a semiconductor wafer is positioned on the passive thermal transfer plate 33, the temperature of the semiconductor wafer may be equalised or substantially equalised to a temperature of the weighing chamber 31, depending on how long the semiconductor wafer is loaded on the passive thermal transfer plate 33.

The passive thermal transfer plate 33 may comprise an intermediate mechanism, for example a plurality of actuator pins, for receiving the semiconductor wafer from the end effector 1 and for lowering the semiconductor wafer onto a surface of the passive thermal transfer plate 33.

The semiconductor wafer mass metrology apparatus 25 further comprises an active thermal transfer plate 35 and a controller 37.

A plurality of Peltier devices 39 are attached to a bottom side of the active thermal transfer plate 35. Each Peltier device 39 has a heat sink 41 attached to the bottom side thereof. An air flow 43 can be provided in a region 45 beneath the bottom side of the thermal transfer plate 35 in order to remove heat from the Peltier devices 39 and from the heat sinks 41.

When a semiconductor wafer is positioned on the active thermal transfer plate 35, heat is conducted from the semiconductor wafer to the active thermal transfer plate 35. The Peltier devices 39 are operable to actively dissipate the heat load removed from the semiconductor wafer by actively removing heat from the active thermal transfer plate 35.

The active thermal transfer plate 35 may comprise an intermediate mechanism, for example a plurality of actuator pins, for receiving the semiconductor wafer from the end effector 1 and for lowering the semiconductor wafer onto a surface of the active thermal transfer plate 35.

The semiconductor wafer mass metrology apparatus 25 is configured to use the end effector 1 of the first embodiment of the present invention to remove a semiconductor wafer from a wafer container such as a FOUP and to transport the semiconductor wafer to the active thermal transfer plate 35.

For example, the apparatus 25 may comprise a robot and/or a robotic arm having the end effector 1 and configured to use the end effector 1 to transport the semiconductor wafer.

While the semiconductor wafer is being transported to the active thermal transfer plate 35, the temperature of the semiconductor wafer is sensed using the thermocouple 19 in the end effector 1, and a temperature of the semiconductor wafer is calculated by the microprocessor 21 of the end effector 1. For example, when the semiconductor wafer is removed from the wafer container it may have a temperature of approximately 70° C., for example, due to a preceding processing step performed on the semiconductor wafer before it was loaded into the wafer container.

The temperature of the semiconductor wafer calculated by the microprocessor 21 is communicated to the controller 37 of the apparatus 25, for example via a robotic arm.

The controller 37 is configured to control a subsequent duration of cooling of the semiconductor wafer by the active thermal transfer plate 35 based on the temperature of the semiconductor wafer calculated by the microprocessor 21.

In particular, the controller 37 is configured to control the duration of cooling of cooler semiconductor wafers to be shorter than the duration of cooling of hotter semiconductor wafers. Where the temperature of a semiconductor wafer is equal to, or within a predetermined range of, a desired temperature, for example the temperature of the weighing chamber 31, it may be decided to not cool the semiconductor wafer using the active thermal transfer plate 35. In other words, the duration of cooling of the semiconductor wafer by the active thermal transfer plate 35 may be controlled to be zero.

In this embodiment, the controller 37 is configured to categorise each incoming semiconductor wafer as either “cold” or “hot” based on temperature of the semiconductor wafer calculated by the microprocessor 21, and to control a duration of cooling of the semiconductor wafer by the active thermal transfer plate 35 based on this categorisation.

For example, the temperature of the semiconductor wafer calculated by the microprocessor 21 may be compared to a predetermined threshold value to see if the temperature is greater than (or greater than or equal to) the predetermined threshold value. When the temperature is greater than (or greater than or equal to) the predetermined threshold value, the semiconductor wafer may be categorised as being “hot”, and where this is not the case the semiconductor wafer may be categorised as being “cold”.

Semiconductor wafers categorised as being “hot” may be cooled for a first duration, whereas semiconductor wafers categorised as being “cold” may be cooled for a shorter second duration, which may for example be zero (in other words the “cold” wafers may not be cooled by the active thermal transfer plate 35).

In this embodiment, the duration of cooling of the semiconductor wafer by the active thermal transfer plate 35 is controlled by controlling an amount of time that the semiconductor wafer is loaded onto the active thermal transfer plate. Thus, the controller 37 may control a time at which the semiconductor wafer is loaded onto the active thermal transfer plate 35 and a time at which the semiconductor wafer is unloaded from the active thermal transfer plate 35 so as to appropriately control the duration of cooling of the semiconductor wafer by the active thermal transfer plate 35. As mentioned above, the amount of time that the semiconductor wafer is loaded onto the active thermal transfer plate 35 may be controlled to be zero.

In other embodiments, the controller 37 may alternatively, or additionally, control an amount of active cooling of the active thermal transfer plate 35. For example, the controller 37 may control a power supplied to the Peltier devices 39, so as to change a rate of cooling provided by the Peltier devices 39.

In alternative embodiments, the cooling of the semiconductor wafer may be controlled uniquely based on the temperature of the semiconductor wafer calculated by the microprocessor 21, for example using a relationship that relates a temperature of the semiconductor wafer calculated by the microprocessor 21 with an appropriate duration of cooling of the semiconductor wafer. Such a relationship may be predetermined in advance by appropriate experimentation.

After the semiconductor wafer has been cooled by the active thermal transfer plate 35, or cooling using the active thermal transfer plate 35 has been skipped, the semiconductor wafer is transported to the passive thermal transfer plate 33 and loaded on the passive thermal transfer plate 33.

The semiconductor wafer may be transported from the active thermal transfer plate 35 to the passive thermal transfer plate 35 using an end effector 1 according to the first embodiment of the present invention. This may be a same end effector that is used to transport the semiconductor wafer to the active thermal transfer plate 35, or a different end effector. Alternatively, a different type of end effector may be used to transport the semiconductor wafer to the passive thermal transfer plate 33.

As mentioned above, when the semiconductor wafer is positioned on the passive thermal transfer plate 33, the temperature of the semiconductor wafer may be equalised or substantially equalised to a temperature of the weighing chamber 31, depending on how long the semiconductor wafer is loaded on the passive thermal transfer plate 33.

Subsequently, the semiconductor wafer is removed from the passive thermal transfer plate 33 and transported into the measurement chamber 31 and loaded on the weighing pan, so that the weight of the semiconductor wafer can be measured using the weighing balance 27.

The apparatus 25 is configured to calculate a mass of the semiconductor wafer based on at least the output of the weighing balance 27. The controller 37 may be configured to calculate the mass of the semiconductor wafer based on at least the output of the weighing balance 27.

In the above embodiment, or in an alternative embodiment, the end effector 1 according to the first embodiment of the present invention may be used to detect the temperature of the semiconductor wafer when transporting the semiconductor wafer to the passive thermal transfer plate 33. Thus, a duration of cooling of the semiconductor wafer by the passive thermal transfer plate 33 may be controlled by the controller 37 on the basis of the temperature of the semiconductor wafer calculated by the microprocessor 21 when the end effector 1 transports the semiconductor wafer to the passive thermal transfer plate 33.

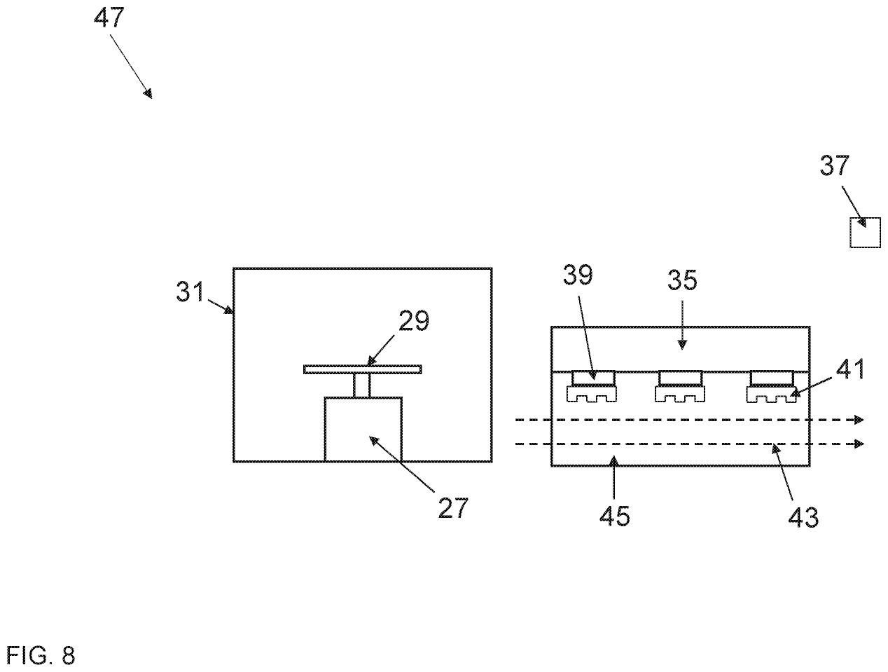

FIG. 8 shows a semiconductor wafer mass metrology apparatus 47 according to a fourth embodiment. The semiconductor wafer mass metrology apparatus according to the fourth embodiment differs from the third embodiment in that the passive thermal transfer plate 33 of the third embodiment is omitted. The other features of this embodiment may otherwise be the same as those of the third embodiment discussed above, so these features are not described again in detail.

In the fourth embodiment, the semiconductor wafer may be transported directly to the weighing chamber 31 from the active thermal transfer plate 35.

In this embodiment, the active thermal transfer plate 35 is preferably controlled to substantially match the temperature of the semiconductor wafer to the temperature of the weighing chamber 31.

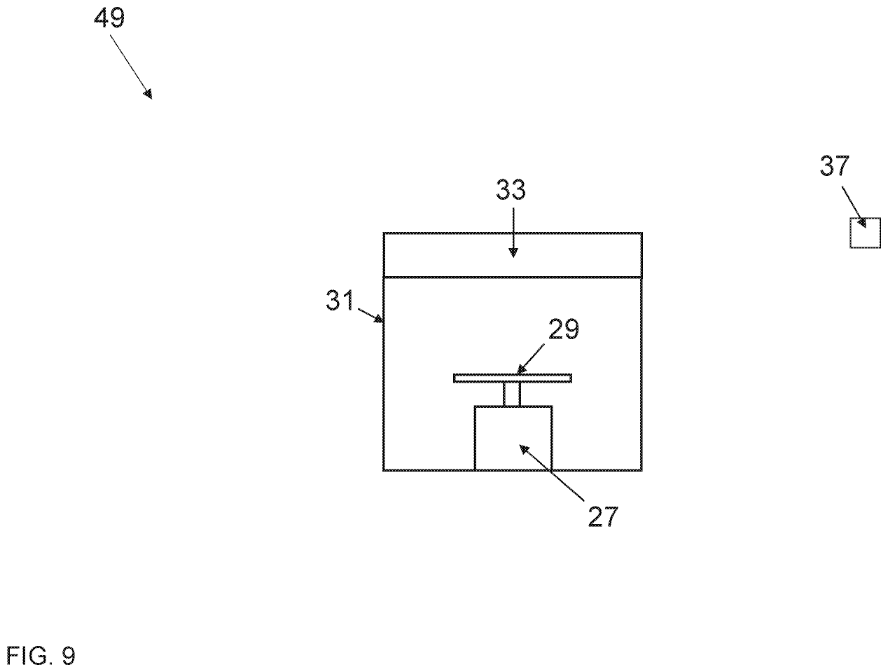

FIG. 9 shows a semiconductor wafer mass metrology apparatus 49 according to a fifth embodiment. The semiconductor wafer mass metrology apparatus according to the fifth embodiment differs from the third embodiment in that the active thermal transfer plate 35 is omitted.

Thus, in the fifth embodiment the thermocouple 19 is used to sense a temperature of a semiconductor wafer as it is transported by the end effector 1 and before it is loaded onto the passive thermal transfer plate 33.

The controller 37 then controls a duration of cooling of the semiconductor wafer by the passive thermal transfer plate 33 in a similar manner to that discussed above in relation to the third embodiment, for example by controlling an amount of time that the semiconductor wafer is loaded onto the passive thermal transfer plate 33.

The above described embodiments relate to cooling the semiconductor wafer. However, in other embodiments the active and/or passive thermal transfer plate may instead be used to heat the semiconductor wafer.

The active and/or passive thermal transfer plate of the embodiments described above may be replaced with other types of cooling or heating devices.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

1. An end effector for supporting a wafer, the end effector having a temperature sensor that is configured to sense a temperature of a wafer supported by the end effector.

2. The end effector according to claim 1, wherein the temperature sensor is configured to be in thermal contact with a wafer supported by the end effector.

3. The end effector according to claim 1, wherein the temperature sensor comprises a thermocouple.

4. The end effector according to claim 1, wherein the temperature sensor is embedded, or partially embedded, in the end effector.

5. The end effector according to claim 1, where the end effector comprises a plurality of pads that are configured to support the wafer, and wherein the temperature sensor is embedded, or partially embedded, in one of the pads.

6. The end effector according to claim 1, wherein the end effector comprises a main body having a through hole, and wherein the temperature sensor is located, or partially located, in the through hole.

7. The end effector according to claim 6, wherein the end effector comprises a tubular part located in the through hole.

8. The end effector according to claim 7, wherein the tubular part comprises a material having a lower thermal conductivity than a material of the main body of the end effector.

9. The end effector according to claim 8, wherein the material having the lower thermal conductivity comprises polyoxymethylene.

10. The end effector according to claim 7, wherein the end effector comprises a cap or cover on an upper side of the tubular part.

11. The end effector according to claim 10, wherein the cap or cover comprises a material having a higher thermal conductivity than a material of the tubular part.

12. The end effector according to claim 11, wherein the material having the higher thermal conductivity comprises Aluminium.

13. The end effector according to claim 10, wherein the temperature sensor is attached to an underside of the cap or cover.

14. The end effector according to claim 13, wherein the temperature sensor is attached to the underside of the cap or cover using a thermally conductive adhesive, for example thermal epoxy.

15. The end effector according to claim 1, wherein the end effector comprises a controller that is configured to receive an output of the temperature sensor.

16. The end effector according to claim 15, wherein the controller is configured to calculate a temperature based on the output of the temperature sensor.

17. The end effector according to claim 16, wherein the controller is configured to calculate the temperature using a calibration algorithm.

18. A robotic arm having the end effector according to claim 1.

19. An apparatus comprising:
a cooling or heating part for cooling or heating a wafer; and
the end effector according to claim 1, wherein the apparatus is configured to use the end effector to transport the wafer to the cooling or heating part.

20. The apparatus according to claim 19, wherein the apparatus further comprises a robotic arm having the end effector.

21. The apparatus according to claim 19, wherein the apparatus further comprises a controller that is configured to control a duration of cooling or heating of the wafer by the cooling or heating part based on an output of the temperature sensor.

22. The apparatus according to claim 21, wherein the controller is configured to control a duration of cooling or heating of the wafer to be zero when a temperature sensed by the temperature sensor is equal to, or within a predetermined range of, a predetermined temperature.

23. The apparatus according to claim 21, wherein the controller is configured to skip an available cooling or heating step if a temperature difference between a temperature sensed by the temperature sensor and a predetermined temperature is less than ±2K, or ±1K, or ±0.5K, or ±0.1K.

24. The apparatus according to claim 19, wherein the apparatus is a wafer mass metrology apparatus that further comprises a measurement area.

25. A method comprising:
supporting a wafer using an end effector; and
sensing a temperature of the wafer using a temperature sensor of the end effector.

26. The method according to claim 25, wherein the method further comprises controlling a duration of cooling or heating of the wafer based on an output of the temperature sensor.

27. The method according to claim 26, wherein the method comprises controlling a duration of cooling or heating of the wafer to be zero when a temperature sensed by the temperature sensor is equal to, or within a predetermined range of, a predetermined temperature.

28. The method according to claim 25, wherein the method comprises skipping an available cooling or heating step if a temperature difference between a temperature sensed by the temperature sensor and a predetermined temperature is less than ±2K, or ±1K, or ±0.5K, or ±0.1K.

29. The method according to claim 25, wherein the method is a wafer mass metrology method, and wherein the method further comprises subsequently loading the wafer onto a measurement area of a wafer mass metrology apparatus.
